(19) United States
(12) Patent Application Publication
(10) Pub. No.: US 2026/0282546 A1
(43) Pub. Date: Sep. 17, 2026

(54) DISPLAY DEVICE

(71) Applicant: E Ink Holdings Inc., HSINCHU (TW)

(72) Inventors: Yu-Sheng LIN, HSINCHU (TW); Yu Yi CHEN, HSINCHU (TW)

(21) Appl. No.: 19/439,499

(22) Filed: Jan. 5, 2026

(30) Foreign Application Priority Data
Mar. 12, 2025 (TW) 114109248

(51) Int. Cl. H10D 86/40; H10D 86/60

(52) U.S. Cl. CPC H10D 86/443; H10D 86/60

(57) ABSTRACT

A display device includes a display panel and an external circuit component. The display panel has a display area and a peripheral area, and includes pixels in the display area and trances in the peripheral area. In a bonding area of the peripheral area, one of the trances includes a strip part and an oblique part connecting to the strip part. The extending direction of the strip part is parallel to an edge of the display panel, and an obtuse angle is formed between the oblique part and the strip part. The external circuit component includes pads disposed on the trances and electrically connected to the trances. One of the pads includes a beveled part and a straight part connecting to the beveled part. In the normal line of the display panel, the beveled part overlaps the oblique part, and the straight part overlaps the strip part.

### CROSS-REFERENCE TO RELATED APPLICATION

This application claims priority to Taiwan Application Serial Number 114109248, filed Mar. 12, 2025, which is herein incorporated by reference in its entirety.

### BACKGROUND

### Field of Invention

The present disclosure relates to a display device. More particularly, the present disclosure relates to a display device including an external circuit component.

### Description of Related Art

As the requirements for resolution of display devices increase, in order to meet the design requirements of narrow bezels, the trace density of the display panel in the peripheral area is bound to increase, and the trace turning extent in the bonding area of the peripheral area also becomes larger. Therefore, when the pads of the external circuit component are electrically connected to the corresponding traces in the bonding area, the pads easily overlap other traces due to slight offsetting, resulting in short circuit or parasitic capacitance.

### SUMMARY

At least one embodiment of the present disclosure provides a display device that can reduce the situation where the pads of the external circuit component overlaps other traces in the bonding area to cause short circuit or parasitic capacitance, thereby improving the yield and electrical performance.

The display device according to at least one embodiment of the present disclosure includes a display panel and an external circuit component. The display panel has a display area and a peripheral area adjacent to the display area, and includes multiple pixels disposed in the display area and multiple trances disposed in the peripheral area. The trances include a first trace, and the peripheral area has a bonding area. In the bonding area, the first trace includes a first strip part and a first oblique part connecting to the first strip part, the extending direction of the first strip part is parallel to an edge of the display panel, and a first obtuse angle is formed between the first oblique part and the first strip part. The external circuit component includes multiple pads. The pads are disposed on the trances in the bonding area respectively and are electrically connected to the trances respectively. The pads include a first pad, and the first pad includes a first beveled part and a first straight part connecting to the first beveled part. In the normal line of the display panel, the first beveled part overlaps the first oblique part, and the first straight part overlaps the first strip part.

The display device according to at least another embodiment of the present disclosure includes a display panel and an external circuit component. The display panel has a display area and a peripheral area adjacent to the display area, and includes multiple pixels disposed in the display area and multiple trances disposed in the peripheral area. The trances include a first trace, and the peripheral area has a bonding area. In the bonding area, the first trace includes a first strip part and a first oblique part connecting to the first strip part, the extending direction of the first strip part is parallel to an edge of the display panel, and a first obtuse angle is formed between the first oblique part and the first strip part. The external circuit component includes multiple pads. The pads are disposed on the trances in the bonding area respectively and are electrically connected to the trances respectively. The pads include a first pad, and the first pad includes a first beveled part and a first straight part connecting to the first beveled part. In the normal line of the display panel, the first beveled part overlaps the first oblique part. The first straight part has a first side parallel to the extending direction of the first strip part. The first beveled part has a first beveled side connecting to the first side. A second obtuse angle is formed between the first beveled side and the first side, and the first obtuse angle is equal to the second obtuse angle.

It is to be understood that both the foregoing general description and the following detailed description are by examples, and are intended to provide further explanation of the present disclosure as claimed.

### BRIEF DESCRIPTION OF THE DRAWINGS

The present disclosure can be more fully understood by reading the following detailed description of the embodiment, with reference made to the accompanying drawings as follows:

FIG. 1 is a schematic top view of a display device according to at least one embodiment of the present disclosure.

FIG. 2A is an enlarged diagram of region A in FIG. 1.

FIG. 2B is an enlarged diagram of region B in FIG. 1.

### DETAILED DESCRIPTION

The embodiments of the present disclosure are discussed in detail below. It will be appreciated, however, that the embodiments provide many applicable concepts which may be implemented in a wide variety of specific contexts. The discussed and disclosed embodiments are for illustrative purposes only and are not intended to limit the scope of patent applications in this case.

In the following description, in order to clearly present the technical features of the present disclosure, the dimensions of elements in the drawings will be enlarged in unequal proportions. Therefore, the description and explanation of the following embodiments are not limited to the sizes and shapes presented by the elements in the drawings, but should cover the sizes, shapes, and deviations of the two due to actual manufacturing processes and/or tolerances. For example, the flat surface shown in the drawings may have rough and/or non-linear characteristics, and the acute angle shown in the drawings may be round. Therefore, the elements presented in the drawings in this case are mainly for illustration, and are not intended to accurately depict the actual shape of the elements, nor are they intended to limit the scope of patent applications in this case.

Furthermore, the words “about”, “approximately” or “substantially” used in the present disclosure not only cover the clearly stated numerical values and numerical ranges, but also cover those that can be understood by a person with ordinary knowledge in the technical field to which the present disclosure belongs. The permissible deviation range can be determined by the error generated during measurement, and the error is caused, for example, by limitations of the measurement system or process conditions. For example, two objects (such as the plane or traces of a substrate) are “substantially parallel” or “substantially perpendicular,” where “substantially parallel” and “substantially perpendicular,” respectively, mean that parallelism and perpendicularity between the two objects can include non-parallelism and non-perpendicularity caused by permissible deviation ranges.

In addition, “about” may mean within one or more standard deviations of the above values, such as within ±30%, ±20%, ±10%, or ±5%. Such words as “about”, “approximately”, or “substantially” as appearing in the present disclosure may be used to select an acceptable range of deviation or standard deviation according to optical properties, etching properties, mechanical properties, or other properties, rather than applying all of the above optical properties, etching properties, mechanical properties, and other properties with a single standard deviation.

The spatial relative terms used in the present disclosure, such as “below,” “under,” “above,” “on,” and the like, are intended to facilitate the recitation of a relative relationship between one element or feature and another as depicted in the drawings. The true meaning of these spatial relative terms includes other orientations. For example, the relationship between one element and another may change from “below” and “under” to “above” and “on” when the drawing is turned 180 degrees up or down. In addition, spatially relative descriptions used in the present disclosure should be interpreted in the same manner.

It should be understood that while the present disclosure may use terms such as “first”, “second”, “third” to describe various elements or features, these elements or features should not be limited by these terms. These terms are primarily used to distinguish one element from another or one feature from another. In addition, the term “or” as used in the present disclosure may include, as appropriate, any one or a combination of the listed items in association.

Moreover, the present disclosure may be implemented or applied in various other specific embodiments, and the details of the present disclosure may be combined, modified, and altered in various embodiments based on different viewpoints and applications, without departing from the idea of the present disclosure.

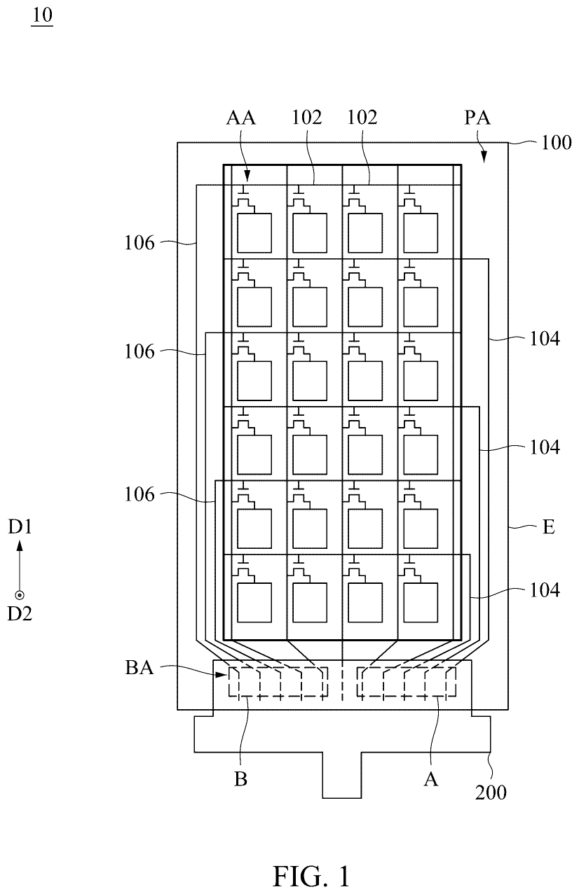

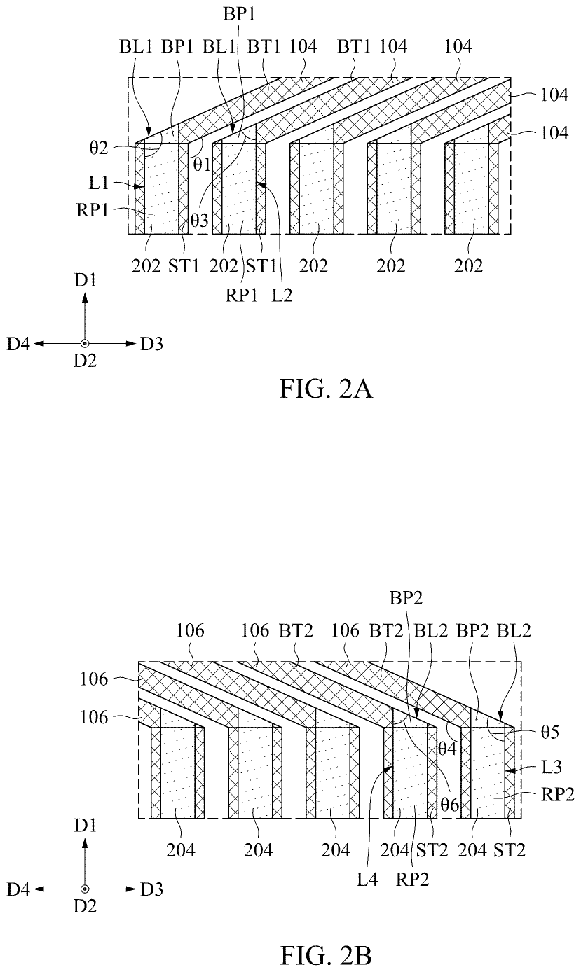

FIG. 1 is a schematic top view of a display device 10 according to at least one embodiment of the present disclosure. FIG. 2A is an enlarged diagram of region A in FIG. 1. FIG. 2B is an enlarged diagram of region B in FIG. 1. Referring to FIG. 1, the display device 10 includes a display panel 100 and an external circuit component 200. The display panel 100 has a display area AA and a peripheral area PA adjacent to the display area AA, and includes multiple pixels 102 and multiple traces 104, 106. The pixels 102 are disposed in the display area AA, the traces 104, 106 are disposed in the peripheral area PA, the traces 104, 106 include a first trace 104, and the peripheral area PA has a bonding area BA.

Referring to FIG. 1 and FIG. 2A, in the bonding area BA, the first trace 104 includes a first strip part ST1 and a first oblique part BT1 connecting to the first strip part ST1. The extending direction of the first strip part ST1 is substantially parallel to an edge E of the display panel 100 extending in a first direction D1. A first obtuse angle θ1 is formed between the first oblique part BT1 and the first strip part ST1.

Referring to FIG. 1, FIG. 2A and FIG. 2B, the external circuit component 200 includes multiple pads 202, 204 disposed on the traces 104, 106 in the bonding area BA respectively and electrically connected to the traces 104, 106 respectively. The pads 202, 204 include a first pad 202, and the first pad 202 includes a first beveled part BP1 and a first straight part RP1 connecting to the first beveled part BP1. In the normal line of the display panel 100, i.e., in a second direction D2 perpendicular to the first direction D1, the first beveled part BP1 overlaps the first oblique part BT1, and the first straight part RP1 overlaps the first strip part ST1.

Since the first pad 202 of the external circuit component 200 includes the first beveled part BP1, even if the first pad 202 of the external circuit component 200 is slightly offset when electrically connected to the corresponding first trace 104 of the display panel 100 in the bonding area BA, it is not easy to overlap with other traces, thus reducing short circuit or parasitic capacitance, thereby improving the yield and electrical performance of the display device 10. In addition, by overlapping the first beveled part BP1 and the first oblique part BT1, the electrical connection area between the first pad 202 and the first trace 104 can be increased, thus further enhancing the electrical performance of the display device 10.

Referring to FIG. 1, the pixels 102 are arranged in an array in the display area AA, and the pixels 102 may include pixel electrodes (not labeled) and switching elements (not labeled) electrically connected to the pixel electrodes, such as thin film transistors. The traces 104, 106 may be electrically connected to the pixels 102 respectively, and extend from the display area AA to the peripheral area PA. In some embodiments, the traces 104, 106 may include one of the scan line and the data line electrically connected to the aforementioned switch element and a transfer layer structure electrically connected to one of the scan line and the data line, but the present disclosure is not limited thereto. In other embodiments, the traces 104, 106 may include other signal lines that are not electrically connected to the aforementioned pixel electrode or the aforementioned switch element, such as a constant voltage signal line.

Furthermore, in some embodiments, the external circuit component 200 may include a driver chip, a control circuit, a flexible printed circuit (FPC), or a printed circuit board (PCB) configured with a driver chip, so that the pixels 102 can be driven.

Referring to FIG. 2A, the first straight part RP1 has a first side L1 substantially parallel to the extending direction of the first strip part ST1, the first beveled part BP1 has a first beveled side BL1 connecting to the first side L1, and a second obtuse angle θ2 is formed between the first beveled side BL1 and the first side L1. In some embodiments, the first beveled side BL1 and the extending direction of the first oblique part BT1 are substantially parallel, and the first obtuse angle θ1 is approximately equal to the second obtuse angle θ2. The aforementioned design can effectively reduce the overlap between the first pad 202 of the external circuit component 200 and other traces to cause short circuit or parasitic capacitance when the first pad 202 is electrically connected to the corresponding first trace 104 in the bonding area BA, thereby improving the yield and electrical performance of the display device 10, but the present disclosure is not limited thereto. In other embodiments, according to product requirements, the first beveled side BL1 and the extending direction of the first oblique part BT1 may be designed to be non-parallel, and the first obtuse angle θ1 and the second obtuse angle θ2 may be designed to be unequal.

In addition, the first straight part RP1 further has a second side L2. The first beveled side BL1 is located between the first side L1 and the second side L2, and connects to the first side L1 and the second side L2. The second side L2 is substantially parallel to the extending direction of the first strip part ST1, and a first acute angle θ3 is formed between the first beveled side BL1 and the second side L2. In some embodiments, the second obtuse angle θ2 is substantially complementary to the first acute angle θ3.

Referring to FIG. 1 and FIG. 2B, the traces 104, 106 include a second trace 106. In the bonding area BA, the second trace 106 includes a second strip part ST2 and a second oblique part BT2 connecting to the second strip part ST2. The extending direction of the second strip part ST2 is substantially parallel to the edge E of the display panel 100. A third obtuse angle θ4 is formed between the second oblique part BT2 and the second strip part ST2. The pads 202, 204 include a second pad 204. The second pad 204 includes a second beveled part BP2 and a second straight part RP2 connecting to the second beveled part BP2. In the normal line of the display panel 100 (i.e., the second direction D2), the second beveled part BP2 overlaps the second oblique part BT2, and the second straight part RP2 overlaps the second strip part ST2.

The second straight part RP2 has a third side L3 substantially parallel to the extending direction of the second strip part ST2, the second beveled part BP2 has a second beveled side BL2 connecting to the third side L3, and a fourth obtuse angle θ5 is formed between the second beveled side BL2 and the third side L3. In some embodiments, the second beveled side BL2 and the extending direction of the second oblique part BT2 are substantially parallel, and the third obtuse angle θ4 is approximately equal to the fourth obtuse angle θ5. The aforementioned design can effectively reduce the overlap between the second pad 204 of the external circuit component 200 and other traces to cause short circuit or parasitic capacitance when the second pad 204 is electrically connected to the corresponding second trace 106 in the bonding area BA, thereby improving the yield and electrical performance of the display device 10, but the present disclosure is not limited thereto. In other embodiments, according to product requirements, the second oblique part BT2 and the extending direction of the second beveled side BL2 may be designed to be non-parallel, and the third obtuse angle θ4 and the fourth obtuse angle θ5 may be designed to be unequal.

The second straight part RP2 further has a fourth side L4. The second beveled side BL2 is located between the third side L3 and the fourth side L4, and connects to the third side L3 and the fourth side L4. The fourth side L4 is substantially parallel to the extending direction of the second strip part ST2, and a second acute angle θ6 is formed between the second beveled side BL2 and the fourth side L4. In some embodiments, the fourth obtuse angle θ5 is substantially complementary to the second acute angle θ6.

In addition, as shown in FIG. 2A and FIG. 2B, the first oblique part BT1 of the first trace 104 and the first beveled side BL1 of the first pad 202 are inclined toward a third direction D3 perpendicular to the first direction D1 and the second direction D2, and the second oblique part BT2 of the second trace 106 and the second beveled side BL2 of the second pad 204 are inclined toward a fourth direction D4 perpendicular to the first direction D1 and the second direction D2 and opposite to the third direction D3. In some embodiments, the extending direction of the first oblique strip portion BT1 and the extending direction of the second oblique part BT2 have the same absolute value of slope, but have the opposite directions of slope, and the first beveled side BL1 and the second beveled side BL2 have the same absolute value of slope, but have the opposite directions of slope.

In summary, in at least one embodiment of the display device of the present disclosure, the pad of the external circuit component includes the beveled part, even if the pad of the external circuit component is slightly offset when electrically connected to the corresponding trace of the display panel in the bonding area, it is not easy to overlap with other traces, thus reducing short circuit or parasitic capacitance, thereby improving the yield and electrical performance of the display device. In addition, by overlapping the beveled part of the pad and the oblique part of the trace, the electrical connection area between the pad and the trace can be increased, thus further enhancing the electrical performance of the display device.

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the present disclosure. In view of the foregoing, it is intended that the present disclosure cover modifications and variations of this disclosure provided they fall within the scope of the following claims.

What is claimed is:

1. A display device, comprising:
a display panel, having a display area and a peripheral area adjacent to the display area, and comprising:
a plurality of pixels, disposed in the display area; and
a plurality of trances, disposed in the peripheral area, wherein the trances comprise a first trace, and the peripheral area has a bonding area, wherein in the bonding area, the first trace comprises a first strip part and a first oblique part connecting to the first strip part, an extending direction of the first strip part is parallel to an edge of the display panel, and a first obtuse angle is formed between the first oblique part and the first strip part; and
an external circuit component, comprising a plurality of pads, wherein the pads are disposed on the trances in the bonding area respectively and are electrically connected to the trances respectively, the pads comprise a first pad, and the first pad comprises a first beveled part and a first straight part connecting to the first beveled part, wherein in a normal line of the display panel, the first beveled part overlaps the first oblique part, and the first straight part overlaps the first strip part.

2. The display device of claim 1, wherein the first straight part has a first side parallel to the extending direction of the first strip part, the first beveled part has a first beveled side connecting to the first side, and a second obtuse angle is formed between the first beveled side and the first side.

3. The display device of claim 2, wherein the first obtuse angle is equal to the second obtuse angle.

4. The display device of claim 2, wherein the first beveled side is parallel to an extending direction of the first oblique part.

5. The display device of claim 2, wherein the first straight part further has a second side, the first beveled side is located between the first side and the second side and connects to the first side and the second side, and the second side is parallel to the extending direction of the first strip part, wherein a first acute angle is formed between the first beveled side and the second side.

6. The display device of claim 5, wherein the second obtuse angle is substantially complementary to the first acute angle.

7. The display device of claim 5, wherein the trances further comprise a second trace, wherein in the bonding area, the second trace comprises a second strip part and a second oblique part connecting to the second strip part, a extending direction of the second strip part is parallel to the edge of the display panel, and a third obtuse angle is formed between the second oblique part and the second strip part.

8. The display device of claim 7, wherein an extending direction of the first oblique part and an extending direction of the second oblique part have a same absolute value of slope but have opposite directions of slope.

9. The display device of claim 7, wherein the pads further comprise a second pad, and the second pad comprises a second beveled part and a second straight part connecting to the second beveled part, wherein in the normal line of the display panel, the second beveled part overlaps the second oblique part, and the second straight part overlaps the second strip part.

10. The display device of claim 9, wherein the second straight part has a third side parallel to the extending direction of the second strip part, the second beveled part has a second beveled side connecting to the third side, and a fourth obtuse angle is formed between the second beveled side and the third side.

11. The display device of claim 10, wherein the first beveled side and the second beveled side have a same absolute value of slope but have opposite directions of slope.

12. The display device of claim 10, wherein the third obtuse angle is equal to the fourth obtuse angle.

13. The display device of claim 10, wherein the second beveled side is parallel to an extending direction of the second oblique part.

14. The display device of claim 10, wherein the second straight part further has a fourth side, the second beveled side is located between the third side and the fourth side and connects to the third side and the fourth side, and the fourth side is parallel to the extending direction of the second strip part, wherein a second acute angle is formed between the second beveled side and the fourth side.

15. The display device of claim 14, wherein the fourth obtuse angle is substantially complementary to the second acute angle.

16. The display device of claim 14, wherein the first acute angle is equal to the second acute angle.

17. A display device, comprising:
a display panel, having a display area and a peripheral area adjacent to the display area, and comprising:
a plurality of pixels, disposed in the display area; and
a plurality of trances, disposed in the peripheral area, wherein the trances comprise a first trace, and the peripheral area has a bonding area, wherein in the bonding area, the first trace comprises a first strip part and a first oblique part connecting to the first strip part, an extending direction of the first strip part is parallel to an edge of the display panel, and a first obtuse angle is formed between the first oblique part and the first strip part; and
an external circuit component, comprising a plurality of pads, wherein the pads are disposed on the trances in the bonding area respectively and are electrically connected to the trances respectively, the pads comprise a first pad, and the first pad comprises a first beveled part and a first straight part connecting to the first beveled part, wherein in a normal line of the display panel, the first beveled part overlaps the first oblique part, wherein the first straight part has a first side parallel to the extending direction of the first strip part, the first beveled part has a first beveled side connecting to the first side, and a second obtuse angle is formed between the first beveled side and the first side, wherein the first obtuse angle is equal to the second obtuse angle.
